(19) United States
(12) Patent Application Publication
(10) Pub. No.: US 2020/0136348 A1
(43) Pub. Date: Apr. 30, 2020

(54) SEMICONDUCTOR LASER

(71) Applicant: OSRAM Opto Semiconductors GmbH, Regensburg (DE)

(72) Inventors: Roland Heinrich ENZMANN, Gelugor (MY); Andreas WOJCIK, Regensburg (DE); Hubert HALBRITTER, Dietfurt (DE); Martin Rudolf BEHRINGER, Regensburg (DE); Josip MARIC, Sinzing (DE); Mariel Grace JAMA, Regensburg (DE); Berthold HAHN, Hemau (DE); Christian MÜLLER, Deuerling (DE); Isabel OTTO, Regenstauf (DE)

(73) Assignee: OSRAM Opto Semiconductors GmbH, Regensburg (DE)

(21) Appl. No.: 16/493,062

(22) PCT Filed: Apr. 13, 2018
(86) PCT No.: PCT/EP2018/059555

§ 371 Date: Sep. 11, 2019

(30) Foreign Application Priority Data
Apr. 19, 2017 (DE) 10 2017 108 322.7

(51) Int. Cl. H01S 5/042; H01S 5/02; H01S 5/022; H01S 5/183; H01S 5/323; H01S 5/42

(52) U.S. Cl. CPC H01S 5/0425; H01S 5/021; H01S 5/0224; H01S 5/02248; H01S 2301/176; H01S 5/18311; H01S 5/32316; H01S 5/423; H01S 5/0428

(57) ABSTRACT

A semiconductor laser includes a contact carrier having electrical contact surfaces to electrically contact a semiconductor layer sequence, an electrical connecting line from a main side of the semiconductor layer sequence facing away from the contact carrier and a plurality of capacitors, wherein the connecting line is located on or in the semiconductor layer sequence, at least two of the capacitors are present, the capacitances of which differ by at least a factor of 50, the capacitor having a smaller capacitance is configured to supply the active zone with current immediately after a switch-on operation, and the capacitor having the larger capacitance is configured to a subsequent current supply, the capacitor having the smaller capacitance directly electrically connects to the active zone, and a resistor is arranged between the capacitor having the larger capacitance and the active zone, the resistor having a resistance of at least 100 Ω.

### TECHNICAL FIELD

This disclosure relates to a semiconductor laser.

### BACKGROUND

There is a need to provide a semiconductor laser that can be efficiently contacted and is suitable for generating short laser pulses.

### SUMMARY

We provide a semiconductor laser including a semiconductor layer sequence having an active zone that generates laser radiation and having a first and a second electrical connection region on mutually opposite main sides, a contact carrier having electrical contact surfaces to electrically contact the semiconductor layer sequence, an electrical connecting line from a main side of the semiconductor layer sequence facing away from the contact carrier towards the contact carrier, and a plurality of capacitors, wherein the connecting line is located on or in the semiconductor layer sequence, at least two of the plurality of capacitors are present, the capacitances of which differ by at least a factor of 50, a capacitor of the at least two of the plurality of capacitors having a smaller capacitance is configured to supply the active zone with current immediately after a switch-on operation, and the capacitor having the larger capacitance is configured to a subsequent current supply, the capacitor having a smaller capacitance directly electrically connects to the active zone, and a resistor is arranged between the capacitor of the at least two of the plurality of capacitors having a larger capacitance and the active zone, the resistor having a resistance of at least 100 Ω.

We also provide a semiconductor laser or a surface-emitting semiconductor laser, including a semiconductor layer sequence having an active zone that generates laser radiation and having a first and a second electrical connection region on mutually opposite main sides, a contact carrier having electrical contact surfaces to electrically contact the semiconductor layer sequence, an electrical connecting line from a main side of the semiconductor layer sequence facing away from the contact carrier towards the contact carrier, and a plurality of capacitors, wherein the connecting line is located on or in the semiconductor layer sequence, at least two of the plurality of capacitors are present, the capacitances of which differ by at least a factor of 50, and a capacitor of the at least two of the plurality of the capacitors having the smaller capacitance is configured to supply the active zone with current immediately after a switch-on operation, and the capacitor having the larger capacitance is configured to a subsequent current supply.

### BRIEF DESCRIPTION OF THE DRAWINGS

FIGS. 1A to 1E show schematic sectional representations of method steps of producing a semiconductor laser.

FIGS. 2A and 3A show schematic sectional representations of examples of semiconductor lasers.

FIGS. 2B and 3B show schematic plan views of examples of semiconductor lasers.

FIGS. 4 and 6 to 8 show schematic sectional representations of examples of semiconductor lasers.

FIGS. 5, 9 and 10 show schematic electrical circuit diagrams of examples of semiconductor lasers.

### LIST OF REFERENCE SIGNS

1 semiconductor laser
11 laser emitter
2 semiconductor layer sequence
20 active zone
21 first electrical connection region
22 second electrical connection region
23 electrical connecting line
23a through-connection
24 n-contact layer
25 growth substrate
26 etching stop layer or sacrificial layer
27 p-contact layer
28 p-current spreading layer
29 n-current spreading layer
3 contact carrier
31 first electrical contact surface
32 second electrical contact surface
33 casting body
41 first resonator mirror
42 second resonator mirror
5 functional carrier
51, 52 electrical contact point
6 electronic switching element
7 controllable current source
8 passivation layer
C capacitor
GND ground/earth
L laser radiation
R resistor
S signal line
V supply voltage

### DETAILED DESCRIPTION

Our semiconductor laser is preferably a surface-emitting semiconductor laser. This means that an emission direction and/or a resonator longitudinal axis of the semiconductor laser is parallel or approximately parallel to a growth direction of a semiconductor layer sequence. Alternatively, the semiconductor laser can be an edge-emitting laser.

The semiconductor laser may comprise a semiconductor layer sequence. The semiconductor layer sequence may comprise at least one active zone that generates laser radiation. The active zone operates by electroluminescence.

The semiconductor layer sequence is preferably based on a III-V compound semiconductor material. The semiconductor material is, for example, a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs or such as AlₙGaₘIn₁₋ₙ₋ₘAsₖP₁₋ₖ, wherein 0≤n≤1, 0≤m≤1 and n+m≤1 as well as 0≤k>1. Preferably, the following applies to at least one layer or to all layers of the semiconductor layer sequence: 0<n≤0.8, 0.4≤m<1 and n+m≤0.95 as well as 0<k≤0.5. The semiconductor layer sequence can have dopants and additional components. For the sake of simplicity, however, only the essential components of the crystal lattice of the semiconductor layer sequence are mentioned, that is, Al, As, Ga, In, N or P, even if they can be partially replaced and/or supplemented by small quantities of further substances.

Preferably, the semiconductor layer sequence is based on the material system AlInGaAs.

The semiconductor layer sequence may comprise electrical connection regions on two mutually opposite main sides. One of the connection regions is, for example, a p-contact and the second connection region is an n-contact. The semiconductor layer sequence can be energized via the electrical connection regions.

The semiconductor laser may comprise a contact carrier. The contact carrier may have electrical contact surfaces that electrically contact the semiconductor layer sequence. For example, the contact carrier is that component of the semiconductor laser that mechanically carries and supports the latter. This means that the semiconductor laser would not be mechanically stable without the contact carrier.

The semiconductor laser may have at least one electrical connecting line. The one connecting line or the more connecting lines may extend from a side of the semiconductor layer sequence facing away from the contact carrier to the contact carrier. The connecting line is, for example, an electrical conductor track or an electrical flat ribbon contact. The connecting line can have an electrical through-connection. In particular, by the electrical connecting line the second electrical connection region electrically connects to one of the electrical contact surfaces of the contact carrier, in particular directly electrically connects.

The connecting line may be located on or in the semiconductor layer sequence. That is, the connecting line is preferably mechanically coupled to the semiconductor layer sequence and in particular rigidly connected to the semiconductor layer sequence. In other words, the connecting line is then not a bonding wire.

The semiconductor laser may preferably be a surface-emitting semiconductor laser and may comprise a semiconductor layer sequence having an active zone that generates laser radiation. Two electrical connection regions may be located on mutually opposite main sides of the semiconductor layer sequence. A contact carrier may comprise electrical contact surfaces to electrically contact the semiconductor layer sequence. An electrical connecting line may extend from the main side of the semiconductor layer sequence facing away from the contact carrier to the contact carrier, in particular up to one of the electrical contact surfaces. The connecting line may be located on or in the semiconductor layer sequence.

In other words, the semiconductor laser described here can be a surface-emitting laser, also referred to as vertical cavity surface emitting laser, or VCSEL for short. The semiconductor laser is designed as a flip-chip and preferably has an array of individual emitters. In particular, thin-film technologies, that is to say techniques in which a growth substrate is removed from the semiconductor layer sequence are used, which allows structuring of a semiconductor wafer from both main sides. Thus, in particular galvanically, a plurality of preferably thick platforms such as nickel platforms can be applied on one main side to realize p-contacts and/or n-contacts on a single main side. Alternatively, carriers having plated-through holes can be used, in particular silicon-based carriers, with so-called through-silicon vias.

In addition to the advantages of using thin-film technologies, in particular improved thermal coupling, such a semiconductor laser of flip-chip construction offers further advantages. Thus, bonding wires can be dispensed with, as a result of which lower production costs can be achieved. Omission of bonding wires makes it possible to realize lower inductances on the connecting lines and thus smaller switching times. In addition, there is more freedom in the design of the package of the semiconductor laser. Among other things, lower component heights can be realized, in particular since the bonding wires are omitted. Furthermore, direct mounting on a driver such as an application-specific integrated circuit, ASIC for short, is possible. In addition, an optical system can be attached directly to the semiconductor layer sequence or close to the semiconductor layer sequence without disturbing bonding wires.

Especially in runtime-dependent applications, so-called TOF applications or time-of-flight applications, shorter and shorter light pulses are required also in the sub-nanosecond range. In conventional discrete structures with bonding wire contacting, due to relatively high inductances typically correlated with conductor tracks on a printed circuit board or with bonding wires, such switching times are not possible or are possible only with difficulty.

As a result of the fact that the semiconductor layer sequence with the active zone is applied directly to a functional carrier, inductances of the electrical supply lines can be reduced. In particular, the functional carrier can have a rapidly switchable current source or rapidly switchable switches such as field effect transistors or also further circuit components such as capacitors for energy storage, or a complete driver circuit. Thus, the use of thin-film technologies makes it possible to rebond a surface-mountable laser or parts thereof onto a functional carrier. Silicon is particularly suitable as the material for the functional carrier. Various functions can be integrated into the functional carrier, for example, switches, current sources, integrated circuits, memory units and/or sensors such as temperature sensors.

Particularly due to the possible full integration of switching units, low inductivities can be achieved so that short laser pulses can be achieved at a low supply voltage. This can be accompanied with lower power consumption and lower thermal loads. Thus, space saving and cost saving can be achieved, in particular in mobile devices since parts of a driver stage can already be integrated and can be adapted to the semiconductor layer sequence. Faster design cycles are also made possible for a customer since no complex new development of a driver stage is required.

In addition, the semiconductor laser offers the possibility to further minimize the inductance by parallelization of the driver structure and faster rise times of the laser pulses can be achieved. This is possible in particular by using a plurality of parallel switching elements and/or a plurality of parallel supply lines since only a fraction of a total current then flows in each current path. The faster switching times result in particular from the non-linear relationship between the current intensity and the inductance. Stronger current pulses and shorter laser pulses can thus be realized at a higher efficiency. In addition, the overall system has a redundancy and/or a control of the maximum current is simplified.

The semiconductor laser can be surface-mounted. This means that the semiconductor laser is an SMT component.

The contact surfaces of the contact carrier may be located in a common plane. This plane may be oriented in particular parallel to the active zone and/or to the semiconductor layer sequence. The contact surfaces can be completely or partially covered by the semiconductor layer sequence.

Two resonator mirrors may be present. The resonator mirrors can be Bragg mirrors or combined mirrors composed of layers of different refractive indices and final metal layers. It is possible for at least one of the resonator mirrors to be grown epitaxially and located directly on the semiconductor layer sequence. At least one of the resonator mirrors can be used to inject current in the semiconductor layer sequence.

The resonator mirrors and/or the active zone may be oriented parallel to the contact carrier and/or the plane with the contact surfaces. In particular, the resonator longitudinal axis that is, for example, perpendicular to the resonator mirrors, is oriented perpendicular to the active zone. It is thus possible for the generated laser radiation to be emitted during operation in the direction perpendicular to the contact carrier.

An average distance between the connecting line and the semiconductor layer sequence may be at most 5 μm or 3 μm or 1 μm. Alternatively or additionally, this average distance is at least 0.1 μm or 0.2 μm or 0.3 μm. In particular, only a passivation layer for the electrical insulation and passivation of the semiconductor layer sequence lies between the connecting line and the semiconductor layer sequence.

The semiconductor laser may be free of a growth substrate of the semiconductor layer sequence. That is, during the course of the production of the semiconductor laser, the growth substrate may be removed from the semiconductor layer sequence.

The contact carrier may comprise the contact surfaces and a casting body. It is possible for the contact carrier to consist of the contact surfaces and the casting body. In particular, the casting body is produced by injection molding or pressure casting, also referred to as molding. Thus, a material of the casting body is preferably a thermoplastic plastic. The contact surfaces can be formed from one or more metal layers or can also comprise a transparent conductive oxide, TCO for short.

The semiconductor layer sequence may be functionally divided into a multiplicity of individual laser emitters as seen in plan view. Thus, an array of the laser emitters is present that is in plan view, in particular, a regular two-dimensional arrangement of the laser emitters. The individual laser emitters can be of the same construction and, for example, as intended, can emit radiation of the same spectral composition. Alternatively, it is possible for different laser emitters to be provided to generate laser radiation of different wavelengths.

The laser emitters may electrically connect in parallel. This means that all laser emitters are driven electrically at the same time. Alternatively, it is possible for the laser emitters to be electrically controllable individually or separately in groups.

The semiconductor laser may comprise one or more capacitors. The at least one capacitor electrically connects, in particular connects in parallel, to the active zone. Fast pulse rise times of the laser radiation to be generated can be realized via the at least one capacitor. This means that the capacitor or capacitors supply power to the active zone.

The semiconductor laser may comprise one or more further capacitors. The at least one further capacitor may electrically connect to the associated active zone, in particular electrically connect in series, but can also electrically connect in parallel.

At least one of the capacitors may be or a plurality of capacitors may be or groups of the capacitors may be or all capacitors may be jointly assigned to an electronic switching element. This applies in particular to the at least one further capacitor. Via the electronic switching element, the associated capacitance can be controlled, in particular can be supplied with current and/or emptied. The electronic switching element can be a transistor such as a field-effect transistor, FET for short.

A plurality of the capacitors and a plurality of the switching elements may be present. It is possible that there is a one-to-one assignment between the capacitors and the switching elements. In this example, the switching elements can be electrically connected in parallel to one another.

At least two or at least three capacitors may be provided that have the same capacitance. This applies in particular with a tolerance of at most 50% or 25% or 10%. Preferably, the capacitors electrically connect in parallel.

At least two or exactly two capacitors or groups of capacitors may be present, the capacitances of which are greatly different. For example, the capacitances may differ by at least a factor of 20 or 50 or 100. Alternatively or additionally, the capacitances can differ from one another by at most a factor of 1000 or 500 or 200.

The capacitor having the smaller capacitance may be configured to supply the active zone with current immediately after a switch-on process. The at least one capacitor having the larger capacitance can be configured mainly for a subsequent power supply. In this way, particularly short pulse rise times of the laser radiation can be realized.

The capacitor having the smaller capacitance may electrically connect directly to the active zone. Electrically directly can mean that an electrical resistance between the capacitor and the active zone and/or the semiconductor layer sequence is at most 10 Ω or 5 Ω or 2 Ω. Furthermore, it is possible for a resistor to be arranged between the capacitor having the larger capacitance and the active zone. This resistance is, for example, at least 100 Ω or 1 kΩ or 10 kΩ and/or at most 100 kΩ.

The semiconductor laser may comprise one or more functional carriers. At least one electronic component is integrated into the at least one functional carrier. The electronic component is, for example, a capacitor, a coil, a switching element such as a field-effect transistor, a current source such as a controllable or switchable current source or a constant current source or a memory or a control unit such as an ASIC.

The contact carrier may be electrically and/or mechanically fastened to the functional carrier. The contact carrier is preferably soldered onto the functional carrier or adhesively bonded in an electrically conductive manner, in particular without the use of bonding wires.

The capacitor with the smaller capacitance may be monolithically integrated as an electronic component into the functional carrier. Alternatively or additionally, the at least one further capacitor having the larger capacitance is attached, for example, soldered to the functional carrier.

The capacitor having the smaller capacitance may have a capacitance of at most 1 nF or 0.1 nF. The capacitance of the larger capacitor is preferably at least 1 nF or 10 nF or 100 nF.

The active zone may partially or completely cover the at least one electronic component in the functional carrier. In this way, a particularly space-saving arrangement can be achieved.

The functional carrier may have electrical contact points. The electrical contact points may be designed for external electrical contacting of the semiconductor laser. The electrical contact points can be located on a common side, in particular the main side, of the functional carrier, especially on a side facing away from the semiconductor layer sequence. The functional carrier can thus be surface-mountable.

The semiconductor laser can be contacted without bonding wires and/or is free of bonding wires. In this way, low inductances can be realized in the electrical supply lines.

The semiconductor laser may generate laser pulses having a small average pulse duration. For example, the pulse duration is at least 0.2 ns or 0.5 ns and/or at most 5 ns or 2 ns.

Our semiconductor laser is explained in more detail below with reference to the drawing on the basis of examples. Identical reference signs indicate the same elements in the individual figures. However, no relationships to scale are illustrated, but rather individual elements can be represented with an exaggerated size to afford a better understanding.

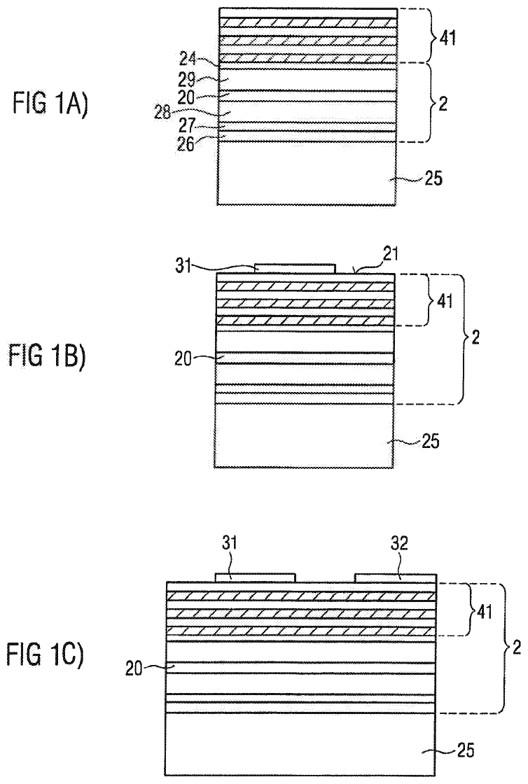

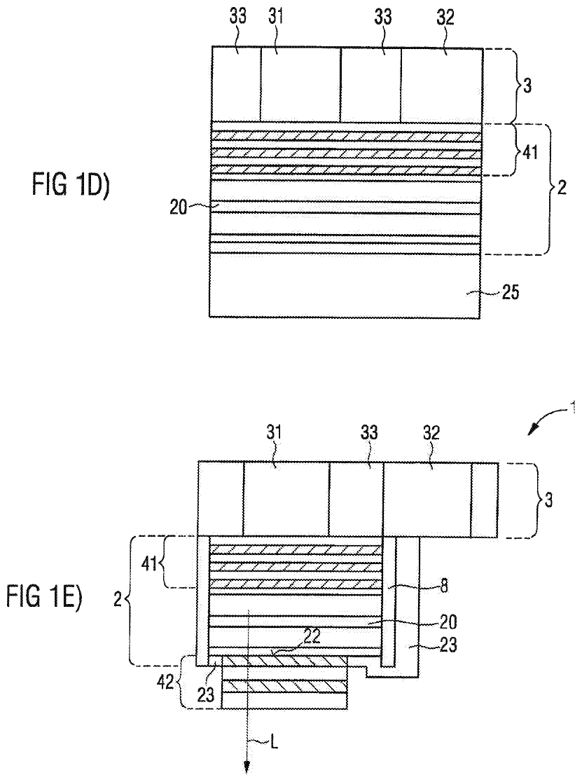

FIGS. 1A-1E illustrate a production method for a semiconductor laser 1. The semiconductor laser 1 is a surface-emitting semiconductor laser, also referred to as VCSEL. The semiconductor laser 1 is designed as a flip-chip using thin-film technology.

According to FIG. 1A, a semiconductor layer sequence 2 based on AlInGaAs is grown on a growth substrate 25. The growth substrate 25 is in particular a GaAs substrate. In the direction away from the growth substrate 25, an etching stop layer 26 or a sacrificial layer 26, a p-contact layer 27, a p-current spreading layer 28, an active zone 20 that generates laser radiation, an n-current spreading layer 29 and an n-contact layer 24 follow. Further layers (not shown) can be present.

On a side facing away from the growth substrate 25, the semiconductor layer sequence 2 is followed by a first resonator mirror 41. The first resonator mirror 41 is preferably a Bragg mirror. The first resonator mirror 41 then has an alternating sequence of layers having high and low refractive indices.

As illustrated in FIG. 1B, the first resonator mirror 41 can be a part of the semiconductor layer sequence 2 and can be grown epitaxially. Alternatively, as illustrated in connection with FIG. 1A, the first resonator mirror 41 can also be produced independently of the semiconductor layer sequence 2.

Furthermore, as shown in FIG. 1B, a first electrical contact surface 31 is produced on a first electrical connection region 21 of the semiconductor layer sequence 2. The first electrical contact surface 31, together with the first resonator mirror 41, can form a combined mirror for the generated laser radiation L. The first electrical contact surface 31 is produced, for example, by vapor deposition.

FIG. 1C illustrates that a second electrical contact surface 32 is likewise formed on the first resonator mirror 41. The two contact surfaces 31, 32 cover a comparatively large proportion of the semiconductor layer sequence 2. Preferably, both contact surfaces 31, 32 are formed from one or more metal layers. The contact surfaces 31, 32 can be of the same construction.

According to FIG. 1D, the contact surfaces 31, 32 are galvanically reinforced, for example. The contact surfaces 31, 32 can thus form platforms made of nickel, for example The contact surfaces 31, 32 are surrounded by a casting body 33. The casting body 33 can end flush with the contact surfaces 31, 32 in the direction away from the growth substrate 25. The finished semiconductor laser 1 can be electrically contacted via the contact surfaces 31, 32. Thus, a contact carrier is formed by the casting body and the reinforced contact surfaces, the contact carrier 3 can be the component that mechanically carries the finished semiconductor laser 1.

In the method step, as shown in connection with FIG. 1E, the semiconductor layer sequence 2 with the first resonator mirror 41 is removed in regions from the contact carrier 3. Resulting side surfaces of the semiconductor layer sequence 2 are provided with a passivation layer 8. The passivation layer is made, for example, of a nitride such as silicon nitride and has, for example, a thickness of approximately 100 nm. A second resonator mirror 42 is applied to a second electrical connection region 22 facing away from the carrier 3, for example, by sputtering and/or vapor deposition. The laser radiation L generated during operation is emitted through the second resonator mirror 42.

An electrical connecting line 23 is formed on the side surfaces of the semiconductor layer sequence 2 and preferably directly on the passivation layer 8. The electrical connecting line 23 surrounds the second resonator mirror 42 all the way around and is in direct contact with the second electrical connection region 22 of the semiconductor layer sequence 2. The second resonator mirror 42, is, for example, a Bragg mirror, and can be currentless. Proceeding from the second connection region 22, the connecting line 23 extends along the passivation layer 8 to the second electrical contact surface 32. Via the preferably metallic connecting line 23, the semiconductor layer sequence 2 can thus be electrically connected in a surface-mountable manner by the contact surfaces 31, 32.

Preferably, prior to production of the passivation layer 8, a lateral current constriction is effected by oxidation of one of the layers of the semiconductor layer sequence, not illustrated.

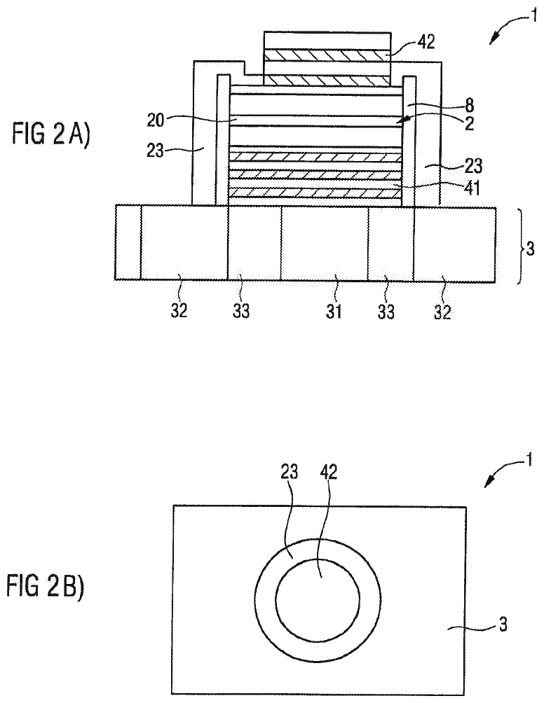

In the example of FIGS. 2A and 2B, the electrical connecting line 23 is pulled all around from the second resonator mirror 42 to the contact carrier 3. As a result, the first electrical contact surface 31 is preferably surrounded all around in a circular manner by the second electrical contact surface 32. The second resonator mirror 42 is likewise surrounded all around by the connecting line 23. Otherwise, the example of FIGS. 2A and 2B corresponds to that of FIGS. 1A-1E.

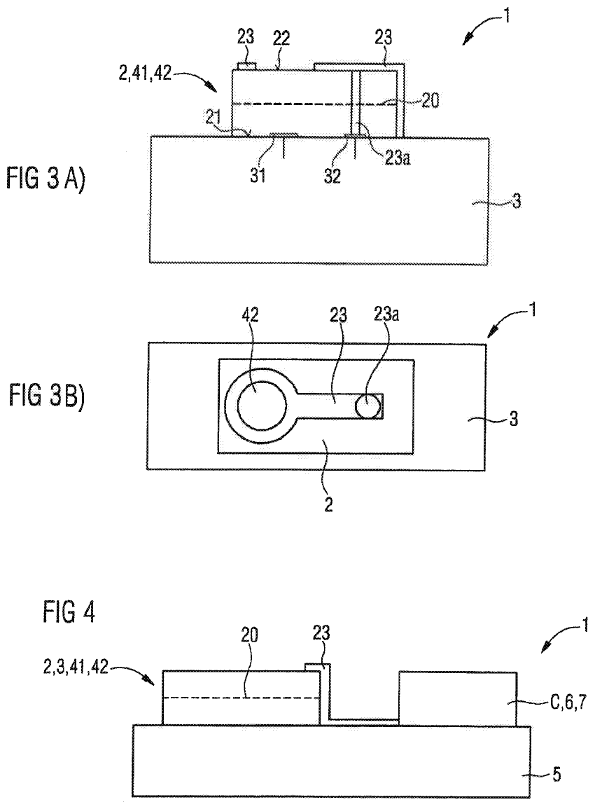

FIGS. 3A and 3B illustrate that the connecting line 23 is either attached to side surfaces of the semiconductor layer sequence 2 and/or has a through-connection 23a, which runs through the semiconductor layer sequence 2 and, viewed in a plan view, is surrounded all around by a material of the semiconductor layer sequence 2 and/or by the resonator mirrors 41, 42. Proceeding from a ring around the second resonator mirror 42, the electrical connecting line 23 can extend in the form of a strip towards the through-connection 23a.

In the example of FIG. 4, the semiconductor laser 1 additionally has a functional carrier 5. The semiconductor layer sequence 2 with the contact carrier 3 is mounted on the functional carrier 5. The contact carrier 3 and the functional carrier 5 can also be formed of a single common component.

Optionally, at least one electronic component such as a capacitor C, an electronic switching element 6 or a controllable current source 7 is arranged on the functional carrier 5 in addition to the semiconductor layer sequence 2. Furthermore, memory chips or integrated circuits such as an ASIC can be present on or in the functional carrier 5, not shown.

The connecting line 23 can extend from a side of the semiconductor layer sequence 20 facing away from the functional carrier 5 to the electronic components C, 6, 7. Alternatively, additional electrical lines (not shown) can be present. Such electrical lines can run on and/or within the functional carrier 5.

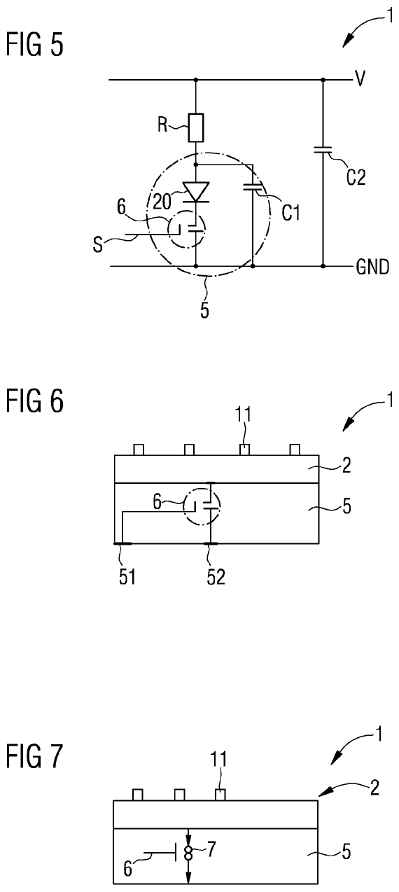

FIG. 5 schematically illustrates an electrical interconnection within the semiconductor laser 1. The active zone 20 is symbolized as a diode and electrically connects to a supply voltage V and a ground contact, also referred to as ground, GND for short. The switching element is a field-effect transistor connected to a signal line. Furthermore, two capacitors C1, C2 are present. The capacitor C1 having the smaller capacitance can electrically connect in parallel with the active zone 20 and can connect directly to the active zone 20 or the semiconductor layer sequence. In parallel with the first capacitor C1, a second capacitor C2 having a larger capacitance is present which connects to the active zone via a resistor R. A corresponding design can be present in all other examples.

Preferably, the switching element 6, the semiconductor layer sequence 2 and the active zone 20 and the capacitor C1 with the smaller capacitance are mounted directly on or in the functional carrier 5. Specifically, the switching element 6 and the capacitor C1 are integrated in the functional carrier 5 based, for example, on silicon. In the optional resistor R and the capacitor C2 having the larger capacitance, these can additionally be components applied onto the functional carrier 5 as shown in FIG. 4.

The capacitors C1, C2 serve as energy stores. A rapid rise in the laser intensity can be achieved by the capacitor C1 with the smaller capacitance so that the capacitor C1 provides a type of switch-on charge for, for example, the first 100 ps or 200 ps of the switch-on process. The capacitor C2 with the larger capacitance subsequently serves as an energy store for the pulsed operated active zone 20.

FIG. 6 illustrates that the switching element 6 is integrated in the functional carrier 5. Electrical contact points 51, 52 are located on an underside of the functional carrier 5 facing away from the semiconductor layer sequence 2, via the contact points 51, 52 the semiconductor laser 1 can be electrically contacted externally. The semiconductor laser 1 is thus voltage-controlled.

As in all other examples, the semiconductor layer sequence 2 is preferably divided into a multiplicity of individual laser emitters 11. Viewed in a plan view, the laser emitters 11 can be arranged in a regular, two-dimensional array. It is possible for the laser emitters 11 all to be electrically connected in parallel or electrically controllable individually or in groups.

Each of the individual laser emitters 11 is preferably annularly surrounded by an electrode such as the electrical connecting line 23 as shown in FIGS. 2A and 2B and viewed in a plan view. The individual laser-active regions, in particular exactly one laser-active region per laser emitter 11, have, for example, a diameter of at least 20 μm and/or of at most 50 μm.

A distance between adjacent laser emitters 11 is, for example, at least 50 μm and/or at most 100 μm. In this way, a grid dimension of the laser emitters 11 can, for example, be at least 70 μm and/or at most 200 μm. A typical edge length of the semiconductor layer sequence 2 with the multiplicity of laser emitters 11 is 1 mm, for example.

FIG. 7 illustrates that a controllable current source 7 is integrated in the functional carrier 5, the current source 7 is controlled via the switching element 6. According to FIG. 7, the semiconductor laser 1 is thus controlled in a current-controlled manner via the controllable and switchable current source 7.

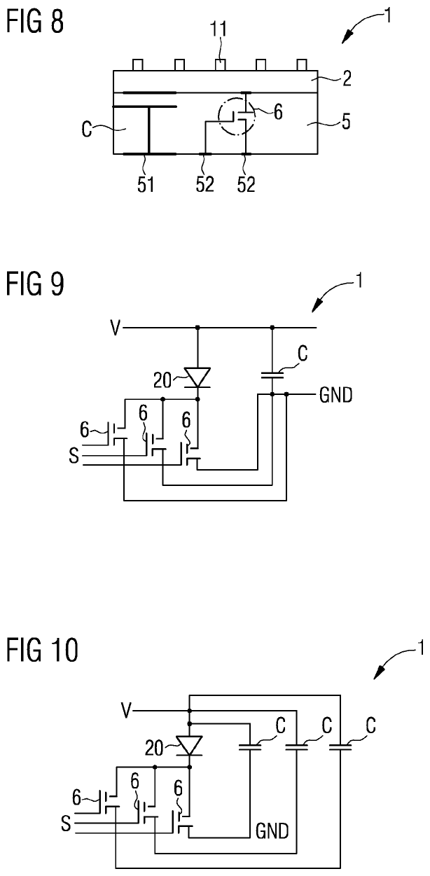

Preferred example FIG. 8 shows a capacitor C integrated in the functional carrier 5 in addition to the switching element 6. In particular, capacitor C corresponds to the capacitor Cl with the smaller capacitance illustrated in FIG. 5.

As in all other examples, it is also possible that the semiconductor layer sequence 2 covers the entire main side of the functional carrier 5 facing away from the contact points 51, 52. The electronic components C, 6, 7 are thus also covered by the semiconductor layer sequence 2. In contrast to this, it is possible for the semiconductor layer sequence 2 to project laterally from the functional carrier 5.

In the circuit construction of FIG. 9, a capacitor C is provided, which is driven by three switching elements 6 that electrically connect in parallel. The switching elements 6 each connect to the signal line S. Thus, a comparatively low current flows via each of the switching elements 6 when the capacitor C is switched so that an inductance can be reduced overall due to the non-linear relationship between the current intensity and the inductance.

The capacitor C in FIG. 9 can correspond to the capacitor C2 having the larger capacitance in FIG. 5. The circuits of FIGS. 5 and 9 can thus be combined with one another. It is possible for the switching elements 6 to be mounted separately on the functional carrier 5 or to be integrated in the functional carrier 5 as shown in FIGS. 6 and 8.

In the example of FIG. 10, three capacitors C are provided that electrically connect in parallel. In other words, the one capacitor of FIG. 9 is divided into three capacitors C. Thus, the inductance can additionally be reduced. Otherwise, the disclosure relating to FIG. 9 apply correspondingly to FIG. 10.

The three capacitors C can be realized by individual separate components or can also be integrated in a common component, which is preferably applied onto the functional carrier 5. Alternatively, all three capacitors C can be integrated in the functional carrier 5 as shown in FIG. 8.

The components shown in the figures follow, unless indicated otherwise, preferably in the specified sequence directly one on top of the other. Layers that are not in contact in the figures are spaced apart from one another. If lines are drawn parallel to one another, the corresponding surfaces are likewise oriented parallel to one another. Likewise, unless indicated otherwise, the relative thickness ratios, length ratios and positions of the drawn components relative to one another are correctly reproduced in the figures.

The lasers described here are not restricted by the description on the basis of the examples. Rather, this disclosure encompasses any new feature and also any combination of features, including in particular any combination of features in the appended claims, even if the feature or combination itself is not explicitly specified in the claims or in examples.

This application claims priority of DE 10 2017 108 322.7, the subject matter of which is incorporated herein by reference.

1-16. (canceled)

17. A semiconductor laser comprising:
a semiconductor layer sequence having an active zone that generates laser radiation and having a first and a second electrical connection region on mutually opposite main sides,
a contact carrier having electrical contact surfaces to electrically contact the semiconductor layer sequence,
an electrical connecting line from a main side of the semiconductor layer sequence facing away from the contact carrier towards the contact carrier, and
a plurality of capacitors,
wherein
the connecting line is located on or in the semiconductor layer sequence,
at least two of the plurality of capacitors are present, the capacitances of which differ by at least a factor of 50,
a capacitor of the at least two of the plurality of capacitors having a smaller capacitance is configured to supply the active zone with current immediately after a switch-on operation, and the capacitor having the larger capacitance is configured to a subsequent current supply,
the capacitor having a smaller capacitance directly electrically connects to the active zone, and
a resistor is arranged between a capacitor of the at least two of the plurality of capacitors having a larger capacitance and the active zone, the resistor having a resistance of at least 100 Ω.

18. The semiconductor laser according to claim 17,
wherein
the semiconductor laser is a surface-emitting semiconductor laser,
the semiconductor laser is a SMT component,
the contact surfaces are located in a common plane,
the active zone is oriented in parallel with the contact carrier and is located between two resonator mirrors,
during operation, a laser radiation is emitted in a direction perpendicular to the contact carrier, and
the semiconductor laser is free of a growth substrate for the semiconductor layer sequence.

19. The semiconductor laser according to claim 17, wherein an average distance of the connecting line from the semiconductor layer sequence is at most 3 μm.

20. The semiconductor laser according to claim 17, wherein the contact carrier consists of the contact surfaces and of a casting body.

21. The semiconductor laser according to claim 17, wherein the contact carrier is a silicon carrier.

22. The semiconductor laser according to claim 17, wherein the semiconductor layer sequence, viewed in a plan view, is subdivided into a plurality of individual laser emitters, and
the laser emitters electrically connect in parallel.

23. The semiconductor laser according to claim 17, comprising a plurality of further capacitors electrically connected in series with the active zone, wherein at least one of the further capacitors is assigned an electronic switching element to control the associated further capacitance.

24. The semiconductor laser according to claim 23, wherein at least one of the further capacitors is assigned a plurality of switching elements and these switching elements are electrically connected in parallel.

25. The semiconductor laser according to claim 17, wherein at least three further capacitors are present, which have the same further capacitance with a tolerance of at most 25%.

26. The semiconductor laser according to claim 17, wherein the capacitances of the at least two capacitors differ by at most a factor of 1000.

27. The semiconductor laser according to claim 17, further comprising at least one functional carrier in which at least one electronic component is integrated and the functional carrier is made of silicon.

28. The semiconductor laser according to claim 27, wherein the contact carrier is electrically and mechanically fastened to the functional carrier.

29. The semiconductor laser according to claim 27, wherein the capacitor having the smaller capacitance is monolithically integrated in the functional carrier as an electronic component, and at least one further capacitor is attached to the functional carrier.

30. The semiconductor laser according to claim 27, wherein at least one controllable current source is integrated in the functional carrier as an electronic component.

31. The semiconductor laser according to claim 27,
wherein the active zone covers the at least one electronic component, and
electrical contact points of the functional carrier for external electrical contacting of the semiconductor laser are applied on a side facing away from the semiconductor layer sequence.

32. The semiconductor laser according to claim 17, that
can be contacted without bonding wires and is free of bonding wires,
wherein the semiconductor laser is provided for time-of-flight applications and configured to emit laser pulses having an average pulse duration of 0.5 ns to 5 ns.

33. A semiconductor laser or a surface-emitting semiconductor laser, comprising:
a semiconductor layer sequence having an active zone that generates laser radiation and having a first and a second electrical connection region on mutually opposite main sides,
a contact carrier having electrical contact surfaces to electrically contact the semiconductor layer sequence,
an electrical connecting line from a main side of the semiconductor layer sequence facing away from the contact carrier towards the contact carrier, and
a plurality of capacitors,
wherein
the connecting line is located on or in the semiconductor layer sequence,
at least two of the plurality of capacitors are present, the capacitances of which differ by at least a factor of 50, and
a capacitor of the at least two of the plurality of the capacitors having the smaller capacitance is configured to supply the active zone with current immediately after a switch-on operation, and the capacitor having the larger capacitance is configured to a subsequent current supply.
